(19) United States
(12) Patent Application Publication
(10) Pub. No.: US 2012/0080980 A1
(43) Pub. Date: Apr. 5, 2012

(54) ELECTROACTIVE ELASTOMER ACTUATOR AND METHOD FOR THE PRODUCTION THEREOF

(76) Inventors: William Kaal, Darmstadt (DE); Sven Herold, Gross-Umstadt (DE); Tobias Melz, Darmstadt (DE)

(21) Appl. No.: 13/377,158

(22) PCT Filed: Jun. 24, 2010
(86) PCT No.: PCT/EP10/03877

§ 371 Date: Dec. 9, 2011

(30) Foreign Application Priority Data
Jun. 26, 2009 (DE) 10 2009 030 693.5

(51) Int. Cl. H01L 41/083; H01L 41/04; B32B 37/14; B32B 37/02; B32B 37/12

(52) U.S. Cl. 310/331; 156/185; 310/367

(57) ABSTRACT

Described is an electroactive elastomer actuator having at least one first band-shaped electroactive elastomer coating and at least one first and one second surface electrode, which are separated by the at least one first electroactive elastomer coating. At least one second electroactive elastomer coating is applied to a surface of the second surface electrode facing away from the electroactive elastomer coating, which forms a band-shaped coating material jointly with the first and second surface electrodes and the first elastomer coating located between the two surface electrodes. The band-shaped coating material is wound around a flat coil form while forming at least two coating material layers. A surface of the first surface electrode facing away from the first elastomer coating makes surface contact with the second electroactive elastomer coating.

### BACKGROUND OF THE INVENTION

1. Field of the Invention

The invention relates to an electroactive elastomer actuator comprising at least one band-shaped electroactive elastomer coating and at least one first and one second surface electrode, which are separated by the at least one first electroactive elastomer coating and furthermore, a method for the production of an electroactive elastomer actuator.

2. Description of the Prior Art

Electroactive elastomer actuators use the converter principle of dielectric elastomers, which belong to the group of electroactive polymers (EAP in short) and are capable of converting electrical energy directly into mechanical work. In contrast to piezoelectric ceramics, which have comparable energy converter properties, electroactive elastomers have very much higher extension properties of greater than 300% and allow substantially free shaping capability at very much lower material density. These properties are used in a way known per se for the construction of actuators and sensors.

An actuator construction is described in WO 2007 029275 having a stack based on an electroactive polymer. A band-shaped electroactive polymer with two band surfaces which contacts a surface-elastic surface electrode and forms a band-shaped coating material. The electrode is folded in a meandering form while forming a plurality of coating material layers located one above another in the form of a stack. By applying an electrical voltage to the surface electrodes, compressing forces act on the individual electroactive polymer coating layers in the coating thickness direction, whereby the actuator is capable of contracting in a controlled way in the coating thickness direction to the individual coating material layers. However, electroactive polymer stack actuators have the disadvantage of requiring complex production, since the individual coating material layers must be stacked one over another with great precision by corresponding folding.

An electroactive polymer actuator connected with a smaller production-technology expenditure is disclosed in WO 2004/109817 A3. This actuator also has a band comprising an electroactive polymer. However, in this case, two band-type electrodes run along the opposing band edges of the electroactive polymer band. The electroactive polymer band which is prefinished in this way is wound in a helical winding arrangement around a cylindrical coil form, which can be separated from the coil from after the winding procedure. Electroactive polymers produced with this so-called rolled construction are technically simple to produce. But actuators configured as hollow rolled bodies, with an actuator action direction oriented in the tube longitudinal axis, have stability problems, caused by the individual polymer band windings being subject to deformations in the event of an axial compression load because their thin-walled overall cylindrical shape impairs the actuator action.

In this context, typical rolled actuators are understood as electroactive polymer bands which are wound around a winding axis, with or without a coil form, and are each provided on one side with a surface electrode, whose actuator action direction is oriented longitudinally to the winding axis. That is, coating thickness variations in the wound polymer band coatings remain unused or unconsidered.

### SUMMARY OF THE INVENTION

The invention is an electroactive elastomer actuator having at least one first band-shaped electroactive elastomer coating and at least one first and one second surface electrode, which are separated by the at least one first electroactive elastomer coating, on the one hand, to have the advantages of stability and actuator efficiency connected to stack actuators known per se and, on the other hand, have the technically simple and cost-effective production mode of actuators manufactured in rolled construction. It is also to be possible to use the electroactive elastomer actuator according to the invention as a modular unit for an expanded construction and expansion of larger dimensioned elastomer actuator systems.

According to the invention, an electroactive elastomer actuator is configured so that at least one second electroactive elastomer coating is applied on a surface facing away from the electroactive elastomer coating to form a band-shaped coating material in conjunction with the first and second surface electrodes and the first elastomer coating located between both surface electrodes. The band-shaped coating material is wound around a plate-shaped coil form, to form at least two coating material layers, in such a way that a surface of the first surface electrode facing away from the first elastomer coating makes surface contact with the second electroactive elastomer coating so that the individual coating material layers have a flat configuration and are interconnected as a one-piece unit by at least one straight band-reshaping area extending transversely to the longitudinal band extension of the band-shaped coating material. The coating material layers form a coating material layer stack oriented orthogonally to the surface extension.

In contrast to the prior art meandering folding technique, which used the known stacked actuators made of film bands, which are coated on both sides with elastically deformable surface electrodes, made of electroactive elastomers, the band-shaped coating material according to the invention allows technically simple winding on a coil form, so that the lower first surface electrode in the coating material makes contact through the winding procedure with the surface of the second electroactive elastomer layer. As a result, no electrical short circuits occur between two surface electrodes integrated in the coating material. On the other hand, the flat configuration of the plurality of stacked coating material layers contact in a one on top of another allows the advantages of a stack actuator to be used, in that the actuator effect can be used in the thickness direction relative to the individual coating material layers.

In a particularly advantageous way, to produce the electroactive elastomer actuator, the band-shaped coating material is wound under pre-tension onto the coil form, whereby the individual coating material layers, which join one another mutually without any air inclusions, form an intimately adhesive joined compound. Through the material stretching in the band longitudinal direction caused by a pre-tension, the band-shaped coating material experiences a coating thickness reduction, which in turn allows a number of individual coating material layers to be wound around the coil form to provide an increased actuator action to provide lift and force, is finally achieved in the thickness direction of the individual coatingmaterials.

Alternatively or in combination with the above-described actuator production using pre-tensioned coating material, an adhesion mediator, for example, in the form of an adhesive glue, which preferably has similar or identical surface-elastic properties as the band-shaped coating material, can be introduced between the respective surfaces of the coating material layers to be brought into mutual contact for a solid cohesion between the individual coating material layers which are brought into mutual contact in the winding procedure.

The selection of shape and size of the coil form required for the production process can fundamentally be freely selected, although in an advantageous embodiment variant the coil form is a plate, so that when winding around the coil form, the coating material layers are oriented parallel to one another on the top and bottom side of the plate-like coil form. The plate-like coil form is advantageously rigid orthogonally to the plate longitudinal extension of the plate but pliable in the longitudinal extension of the plate.

However, with a plate-like configuration of the coil form on which winding occurs around the coil form with the band-shaped coating material under pre-tension, it is particularly advantageous for the coil form to have a high stiffness in the wraparound direction, so that the coil form is prevented from being subjected to undesired deformation due to the applied pre-tension during the winding process.

It is also possible to implement the plate-shaped coil form as yielding orthogonally to the wraparound direction and laterally to the plate extension.

In particular materials or workpieces formed into plates are suitable for this purpose, which have an anisotropic stretching behavior in which the workpiece is suitably structured or is composed of multiple material components. The use of fiber-reinforced plastics is possible for this purpose with suitable fiber orientation providing a desired anisotropy behavior. For example, unidirectionally oriented fibers which stiffen the matrix material in one spatial direction may be implemented in a yielding matrix material , which ensure stiffness in the wraparound direction. However, the matrix material yields orthogonally to the fiber extension. It is also possible to supplement a plate-shaped coil form comprising a stretchable elastomer with at least one and preferably two rigid rod-shaped bodies which flank the coil form on both sides, to make the coil form rigid in the direction of longitudinal extension, but remains stretchable the direction orthogonal thereto.

Metal plates provided with suitable structures can also have corresponding direction-dependent deformation properties.

A possible embodiment variant separates the coil form from the multilayer coating material after completing the winding process. The resulting cavity can be filled with a corresponding material depending on the further use of the elastomer actuator.

The above-described electroactive elastomer actuators are advantageously suitable as individual modules for constructing a stack actuator which can be freely selected in shape and size. If the individual electroactive elastomer actuators as individual modules are stacked one on top of another, the total actuator stroke can be increased. If the individual modules are placed adjacent to one another, the resulting actuator force can be scaled. If a combination of the two above geometries is selected, the total actuator stroke and the actuator force may be scaled.

### BRIEF DESCRIPTION OF THE DRAWINGS

The invention is explained for exemplary purposes hereafter on the basis of exemplary embodiments with reference to the drawings without restriction of the invention. In the figures:

FIG. 1 shows a band-shaped starting material to produce the elastomer actuator configured according to the invention;

FIG. 2 shows a perspective view of the modular individual elastomer actuator;

FIG. 3 shows a stacked arrangement of a stack actuator configured according to the invention, which is composed of four individual actuators;

FIGS. 4a-c show actuator stacks in parallel and series arrangements; and

FIGS. 5 and 6 show coil form alternatives.

### DESCRIPTION OF THE INVENTION

A double film which is band-shaped is shown in FIG. 1 for the construction and production of an electroactive elastomer actuator according to the invention. The double film has a first surface-elastic surface electrode 1, a first electroactive elastomer coating 2, a second surface-elastic surface electrode 3, and a further second electroactive elastomer coating 4. The band-shaped coating material 5, which is configured as a double film, can be produced in the course of an extrusion process or by gluing together two elastomer coatings, which are each provided on one side with a surface electrode. In the illustrated exemplary embodiment, the first and second elastomer coatings 2 and 4 each laterally enclose the surface electrodes 1 and 3, whereby electrical short circuits, for example, due to temporarily occurring moisture bridges, can be prevented.

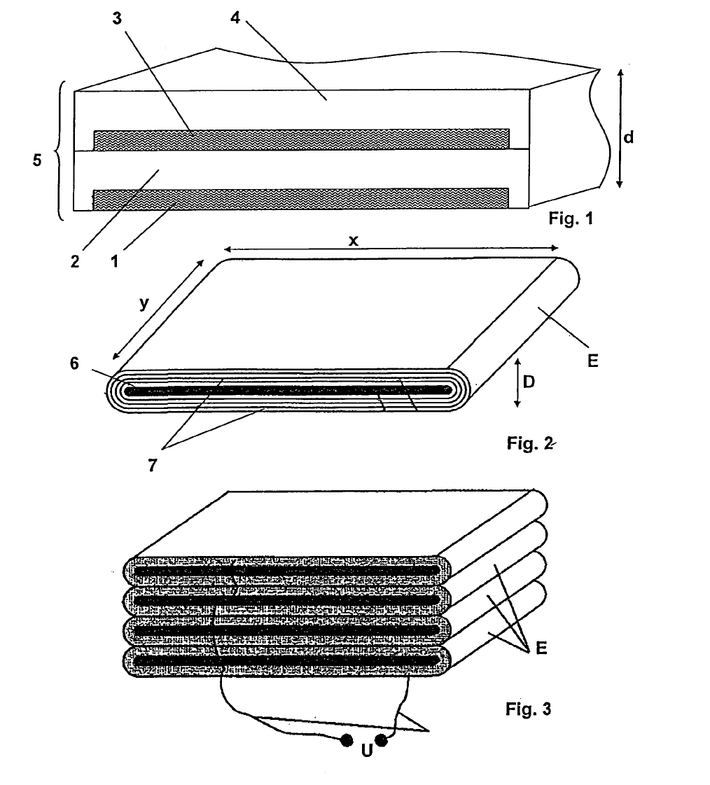

The coating material 5, which is to be stockpiled, is wound around a plate-shaped coil form 6 to produce an electroactive elastomer actuator according to the illustration in FIG. 2, so that the respective lower first surface electrode 1 is brought into contact in each case with the free surface of the second elastomer coating 4 as it is wound one or more times around the coil form 6.

The coil form is preferably configured to be square or rectangular. In order to obtain the most compact possible structure, the band-shaped coating material 5 is wound under pre-tension around the plate-shaped coil form 6, in order to obtain an intimate surface contact between the respective coating material layers 7, on the one hand, and to join the largest possible number of coating material layers one over another, on the other hand, whereby the actuator action in the direction of the thickness of the coating is improved. Through the pre-tension, the band-shaped coating experiences a stretching in the longitudinal direction of the band and, in conjunction therewith, to reduce the band thickness, which increases the number of coating material layers.

Alternatively, an adhesion mediator, which has the same elastic properties as the coating material itself, can be introduced in each case between the individual coating layers.

By winding a plurality of flat coating layers 7 around the plate-shaped coil form 6, along the top and bottom side thereof, the actuator typically has a surface size describable by the side parameters x, y and a layer thickness d, for which the following conditions typically apply: 10 mm≦x, y≦200 mm and 10 μm≦d≦1000 μm. Upon electrical activation of the coating material layers 7, a coating thickness change occurs in the actuator which is oriented in the thickness direction D, which substantially contributes to the total actuator action and can be scaled arbitrarily to provide a wide range of actuator stroke and actuator force by choosing a selected number of individual coating material layers 7 wound around the coil form. In addition, it is possible, by stacking a plurality of the electroactive elastomer actuators E as illustrated in FIG. 2 to be one on top of another, to form a stack of material coating layers 7 made of multiple individual elastomer actuators E according to the illustration in FIG. 3.

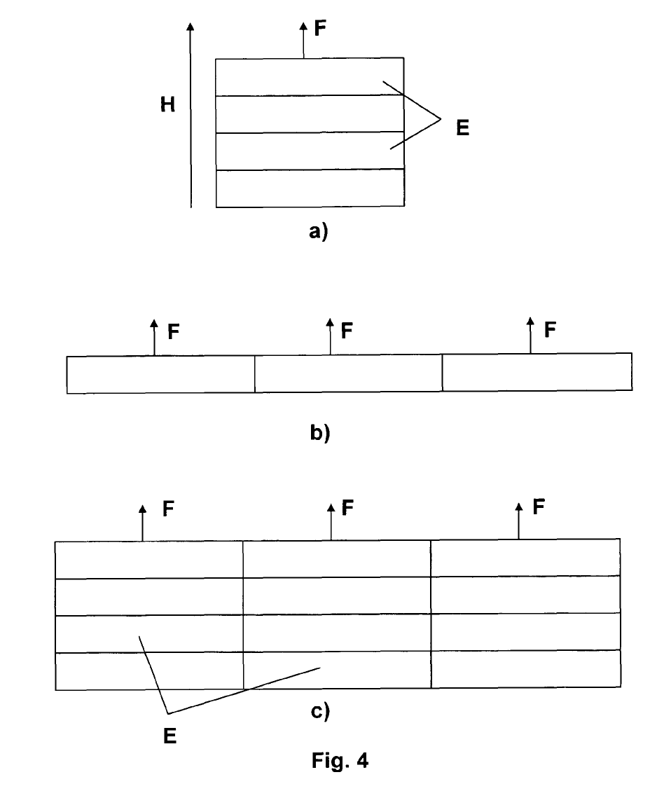

FIG. 4a shows a total stack individual actuators E shown in FIG. 3 in schematic form by rectangles situated one on top of another. Using this arrangement, the total stroke H can be increased by the sum of all individual strokes of the individual elastomer actuators E while the total actuator force nonetheless corresponds to the actuator force F of an individual elastomer actuators. In contrast, if desired, the total actuator force can be increased using the arrangement illustrated in FIG. 4b, in which the individual elastomer actuators E are situated adjacent to one another so that the total actuator force is tripled. Both the actuator force and also the actuator stroke can be scaled using the arrangement illustrated in FIG. 4c.

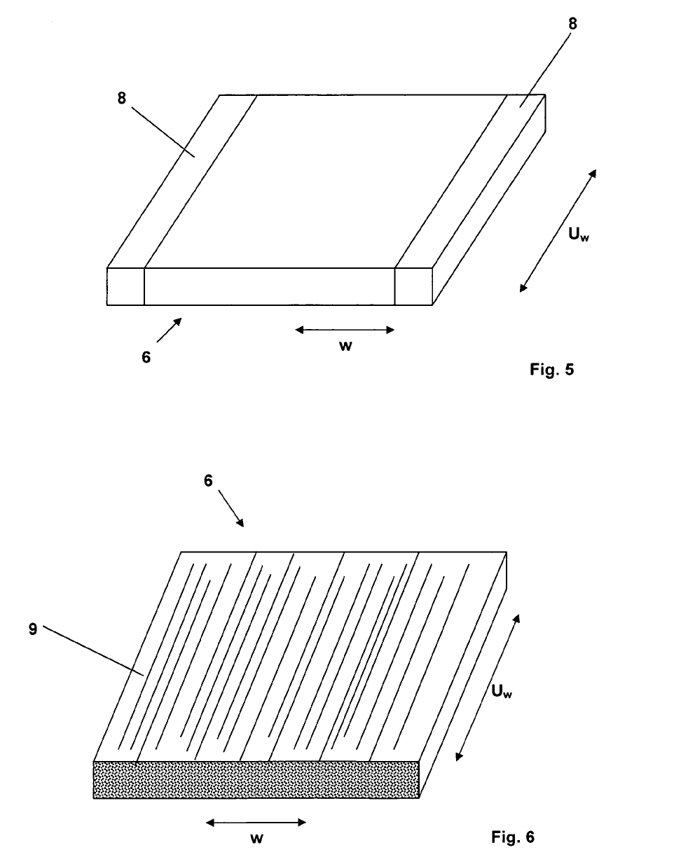

Plate-shaped coil forms 6 are shown in FIGS. 5 and 6. In FIG. 5, the coil form 6 comprises a soft material which yields. In order to prevent the coil form 6 from being deformed (compressed) in the wraparound direction U_{w} by the coating material to be wound under pre-tension onto the coil form, two lateral elements 8 comprising rigid material are attached on both sides of the coil form 6, which prevent a compression in the wraparound direction U_{w}.

In FIG. 6, rigid fibers 9, which are introduced into the elastomer matrix of the coil form 6, prevent a corresponding compression.

However, in both cases, an intrinsic material pliability of the coil form 6 orthogonal to the wraparound direction U_{w} is maintained, see arrow w.

Easy adaptation given actuator requirements is possible by the modular construction of the individual elastomer actuators, according to which a selectable large number of individual actuators can be connected to one another, so that the actuator action can also be scaled as desired. Through a corresponding electrical contact with a supply voltage U of all individual actuators, the system reliability can be increased, because a failure of an individual actuator does not automatically result in destruction of the entire actuator.

### LIST OF REFERENCE NUMERALS

1 first surface electrode

2 first elastomer coating

3 second surface electrode

4 second elastomer coating

5 coating material

6 coil form

7 coating material layers

8 rigid lateral elements

9 rigid fibers

D thickness direction

E elastomer actuator

U_{w} wraparound direction

1-14. (canceled)

15. An electroactive elastomer actuator comprising:
layers of coating material wrapped around a form in one piece, each layer including a first surface electrode, a first electroactive elastomer disposed on the first surface electrode, a second surface electrode disposed on the first electroactive elastomer and a second electroactive elastomer disposed on the second surface electrode with a surface of the second electroactive elastomer contacting a surface of the first surface electrode of another layer of coating material and forming a flat configuration; and
the layers comprise a stack of coating material oriented orthogonal to a direction of surface extension of the actuator.

16. The electroactive elastomer actuator according to claim 15, wherein:
the coating material comprises flat surfaces, is wound around the form, is rigid orthogonally to a direction of extension of the actuator and is pliable in direction of extension of the actuator.

17. The electroactive elastomer actuator according to claim 16, wherein:
the form comprises square or rectangular flat surfaces.

18. The electroactive elastomer actuator according to claim 16, wherein:
the form is metallic or an anisotropic plastic compound.

19. The electroactive elastomer actuator according to claim 17, wherein
the form is metallic or an anisotropic plastic compound.

20. The electroactive elastomer actuator according to claim 15, wherein:
the coating material has surface dimensions measured along x and y directions and a layer thickness d, for which the following conditions apply:
10 mm≦x, y≦200 mm; and
10 μm≦d≦1000 μm.

21. The electroactive elastomer actuator according to claim 16, wherein:
the coating material has surface dimensions measured along x and y directions and a layer thickness d, for which the following conditions apply:
10 mm≦x, y≦200 mm; and
10 μm≦d≦1000 μm.

22. The electroactive elastomer actuator according to claim 17, wherein:
the coating material has surface dimensions measured along x and y directions and a layer thickness d, for which the following conditions apply:
10 mm≦x, y≦200 mm; and
10 μm≦d≦1000 μm.

23. The electroactive elastomer actuator according to claim 18, wherein:
the coating material has surface dimensions measured along x and y directions and a layer thickness d, for which the following conditions apply:
10 mm≦x, y≦200 mm; and
10 μm≦d≦1000 μm.

24. An electroactive elastomer actuator arrangement comprising:
at least two electroactive elastomer actuators each including layers of coating material wrapped around a form in one piece, each layer including a first surface electrode, a first electroactive elastomer disposed on the first surface electrode, a second surface electrode disposed on the first electroactive elastomer and a second electroactive elastomer disposed on the second surface electrode with a surface the second electroactive elastomer contacting a surface of the first surface electrode of another layer of coating material and forming a flat configuration, and a stack of coating material layers oriented orthogonal to a direction of surface extension of the actuator, which are connected in a stack via a shared contact surface; and
the contact surface is an outer surface of uppermost or lowermost layer of one of at least two electroactive elastomer actuators in the stack, and a coating is disposed on the contact surface to provide bonding of two electroactive elastomer actuators together.

25. An electroactive elastomer actuator arrangement according to claim 24 wherein:
the coating material comprises flat surfaces, is wound around the form, is rigid orthogonally to a direction of extension of the actuator and is pliable in direction of extension of the actuator.

26. An electroactive elastomer actuator arrangement according to claim 24 wherein:
the form comprises square or rectangular flat surfaces.

27. An electroactive elastomer actuator arrangement according to claim 24 wherein:
the form is metallic or an anisotropic plastic compound.

28. An electroactive elastomer actuator arrangement according to claim 24 wherein:
the coating material has surface dimensions measured along x and y directions and a layer thickness d, for which the following conditions apply:
10 mm≦x, y≦200 mm; and
10 μm≦d≦1000 μm.

29. The electroactive elastomer actuator arrangement according to claim 24, comprising:
at least two actuators are adjacent to one another and connected to one another via a joint connection.

30. The electroactive elastomer actuator arrangement according to claim 29, wherein:
the form is rigid in a direction of wrapping and coating material is wound around the form under pre-tension.

31. The electroactive elastomer actuator arrangement according to claim 30, wherein
the form is flat; and
the form yields orthogonally to a direction of wrapping the material around the form and laterally to a direction of extension of the actuator.

32. A method for producing an electroactive elastomer actuator including layers of coating material wrapped around a form in one piece, each layer including a first surface electrode, a first electroactive elastomer disposed on the first surface electrode, a second surface electrode disposed on the first electroactive elastomer and a second electroactive elastomer disposed on the second surface electrode with a surface the second electroactive elastomer contacting a surface of the first surface electrode and forming a flat configuration, and the layers comprise a stack of coating material oriented orthogonal to a direction of surface extension of the actuator, comprising the steps:
providing a coating material including the first surface electrode and the second surface electrode, which are applied to opposing surfaces of the first electroactive elastomer, and the at least one second electroactive elastomer coating, which is applied to a surface of the second surface electrode facing away from the first electroactive elastomer;
providing the form; and
winding the coating material around the form to form the at least two coating material layers so the surface of one coating material layer includes the first surface electrode facing away from the first electroactive elastomer makes surface contact with the second electroactive elastomer coating of another coating material layer.

33. The method according to claim 32, wherein:
the coating material connects two electroactive elastomer coatings which are each connected on one side to a surface electrode.

34. The method according to claim 33, comprising:
stockpiling the coating material before providing the coating material.

35. The method according to claim 23, comprising:
winding of the coating material around the form under pretension and supplying an adhesive coating between the material layers while winding the coating material.

36. The method according to claim 32, comprising:
the form is flat and the coating material is wound in a stack oriented orthogonally to a direction of the surface extension of the actuator.
